(19) United States
(12) Patent Application Publication
(10) Pub. No.: US 2009/0090548 A1
(43) Pub. Date: Apr. 9, 2009

(54) CIRCUIT BOARD AND FABRICATION METHOD THEREOF

(75) Inventors: Chao-Wen Shih, Hsin-Chu (TW); Ya-Lun Yen, Hsin-Chu (TW)

Correspondence Address: SCHMEISER OLSEN & WATTS, 18 E UNIVERSITY DRIVE, SUITE # 101, MESA, AZ, 85201, US

(73) Assignee: Phoenix Precision Technology Corporation, Hsin-Chu (TW)

(21) Appl. No.: 12/248,671

(22) Filed: Oct. 9, 2008

(30) Foreign Application Priority Data
Oct. 9, 2007 (TW) 096137778

(51) Int. Cl. H01R 12/04; H01B 13/00; H05K 3/10

(52) U.S. Cl. 174/261; 216/17; 29/846

(57) ABSTRACT

A circuit board is disclosed, including a core board, wherein at least one surface thereof has a core circuit layer with a plurality of conductive lands; a first dielectric layer disposed on the core board and disposed with a plurality of openings for exposing the conductive lands; a first coupling layer disposed on the first dielectric layer, the first coupling layer having a plurality of openings disposed corresponding to the openings of the first dielectric layer; and a first circuit layer disposed on the first coupling layer and a plurality of first conductive vias disposed in the openings of the first coupling layer for electrically connecting to the conductive lands of the core circuit layer. By the formation of the first coupling layer that connects the first circuit layer and the first dielectric layer, the bond strength between the first circuit layer and the first dielectric layer is enhanced, thereby preventing detachment and delamination as encountered in the prior art. The invention further provides a fabrication method of the circuit board described above.

### BACKGROUND OF THE INVENTION

1. Field of the Invention:

The present invention relates generally to a circuit board and a fabrication method thereof, and more particularly to a circuit board with a circuit layer bonded to surface thereof through a material with high bond strength.

2. Description of Related Art:

Currently, in order to increase the precision of the layout of circuit boards for semiconductor chip packages, there has been developed a build-up technique, through which multiple dielectric layers and circuit layers are alternately stacked on surface of a core board, plated through holes and conductive vias being formed in the core board for electrically connecting the circuits of upper and lower surfaces of the core board. Fabrication method of such a core board is shown in FIGS. 1A to 1D.

As shown in FIG. 1A, a core board 10 is provided, a conductive seed layer 11 is formed on one surface of the core board 10 and a first resist layer 12 is formed on the conductive seed layer 11. The first resist layer 12 has a plurality of openings 12a for exposing parts of the conductive seed layer 11.

As shown in FIG. 1B, a first circuit layer 13 is formed by electroplating through the conductive seed layer 11.

As shown in FIG. 1C, the first resist layer 12 and the conductive seed layer 11 covered by the first resist layer 12 are removed.

As shown in FIG. 1D, a circuit built-up structure 20 is formed on the core board 10 and the first circuit layer 13. The circuit built-up structure 20 comprises a dielectric layer 21, a second circuit layer 231 stacked on the dielectric layer 21, and conductive vias 232 formed in the dielectric layer 21 and electrically connecting to the second circuit layer 231, wherein parts of the conductive vias 232 electrically connect to the first circuit layer 13, and the outermost second circuit layer 231 has a plurality of conductive pads 235. Further, an insulative protection layer 24 such as a solder mask layer is formed on surface of the circuit built-up structure 20 and a plurality of openings 24a are formed in the insulative protection layer 24 so as to expose the conductive pads 235.

As bond strength between the dielectric layer 21 made of an insulative material and the second circuit layer 231 made of a metal material is poor, micro cracks can easily occur between the second circuit layer 231 and the dielectric layer 21, which can further lead to peeling or delamination between the second circuit layer 231 and the dielectric layer 21 in subsequent processes or in the use of products.

In addition, if the second circuit layer 231 is patterned into a fine line circuit, the bond strength between the second circuit layer 231 and the dielectric layer 21 will become even weaker. As a result, peeling occurs more easily to the second circuit layer 231 in subsequent processes.

Therefore, there is a need to provide a circuit board that can provide preferred bond strength between the circuit layer and the dielectric layer and meanwhile facilitates application of fine line circuit.

### SUMMARY OF THE INVENTION

According to the above drawbacks, an objective of the present invention is to provide a circuit board and a fabrication method thereof, through which preferred bond strength between the dielectric layer and the circuit layer is provided.

Another objective of the present invention is to provide a circuit board and a fabrication method thereof that can facilitate application of fine line circuit.

In order to attain the above and other objectives, the present invention provides a circuit board, which comprises: a core board, wherein at least one surface thereof has a core circuit layer with a plurality of conductive lands; a first dielectric layer disposed on the core board and having a plurality of openings for exposing the conductive lands; a first coupling layer disposed on the first dielectric layer and having a plurality of openings disposed corresponding to the openings of the first dielectric layer; and a first circuit layer disposed on the first coupling layer and a plurality of first conductive vias disposed in the openings of the first coupling layer for electrically connecting to the conductive lands.

The above-described structure further comprises a circuit built-up structure disposed on the first circuit layer and the first coupling layer, wherein the circuit built-up structure comprises at least a second dielectric layer with a plurality of openings, a second coupling layer disposed on the second dielectric layer and having a plurality of openings disposed corresponding to the openings of the second dielectric layer; and a second circuit layer disposed on the second coupling layer together with a plurality of second conductive vias disposed in the openings of the second coupling layer, parts of the second conductive vias electrically connect to the first circuit layer, and the outermost second circuit layer has a plurality of conductive pads. Further, an insulative protection layer is disposed on the circuit built-up structure, and the insulative protection layer has a plurality of openings for exposing the conductive pads.

The present invention further provides a fabrication method of a circuit board, which comprises: providing a core board, wherein at least one surface thereof has a core circuit layer with a plurality of conductive lands, a first dielectric layer is formed on the core board, and a plurality of openings are formed in the first dielectric layer for exposing the conductive lands; forming a first coupling layer on the first dielectric layer and on the exposed conductive lands in the openings of the first dielectric layer; removing parts of the first coupling layer formed in the openings of the first dielectric layer so as to form a plurality of openings for exposing parts of surfaces of the conductive lands; forming a conductive seed layer on the first coupling layer and in the openings of the first coupling layer; forming a resist layer on the conductive seed layer and forming a plurality of openings in the resist layer for exposing parts of the conductive seed layer, wherein parts of the openings of the resist layer correspond to the openings of the first coupling layer; forming a first circuit layer in the openings of the resist layer and forming first conductive vias in the openings of the first coupling layer by electroplating through the conductive seed layer, the conductive vias electrically connecting to the conductive lands; and removing the resist layer and the conductive seed layer covered by the resist layer.

In the above-described fabrication method, the openings of the first dielectric layer and the first coupling layer can be formed by laser ablation or by exposure and development.

The fabrication method can further comprise forming a circuit built-up structure on the first circuit layer and the first coupling layer, wherein the circuit built-up structure comprises at least a second dielectric layer with a plurality of openings, a second coupling layer formed on the second dielectric layer and having a plurality of openings corresponding to the openings of the second dielectric layer; and a second circuit layer formed on the second coupling layer together with a plurality of second conductive vias formed in the openings of the second coupling layer, parts of the second conductive vias electrically connect to the first circuit layer, and the outermost second circuit layer has a plurality of conductive pads. Further, an insulative protection layer is formed on the circuit built-up structure, and the insulative protection layer has a plurality of openings for exposing the conductive pads.

As the first and second coupling layers of chemical bond characteristic can provide a preferred bonding strength between metal material and non-metal material, the first and second dielectric layers can be firmly connected to the core circuit layer, the first and second circuit layers through the first and second coupling layers respectively, thereby overcoming the conventional problems of micro cracks as well as peeling and delamination and meanwhile providing a strong bond strength for fine line circuits.

### BRIEF DESCRIPTION OF DRAWINGS

FIGS. 1A to 1D are sectional diagrams showing a fabrication method of a conventional circuit board; and

FIGS. 2A to 2G are sectional diagrams showing a fabrication method of a circuit board according to the present invention.

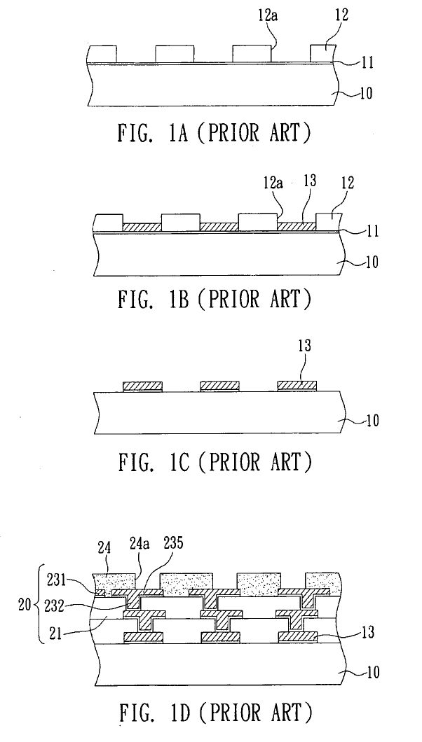

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

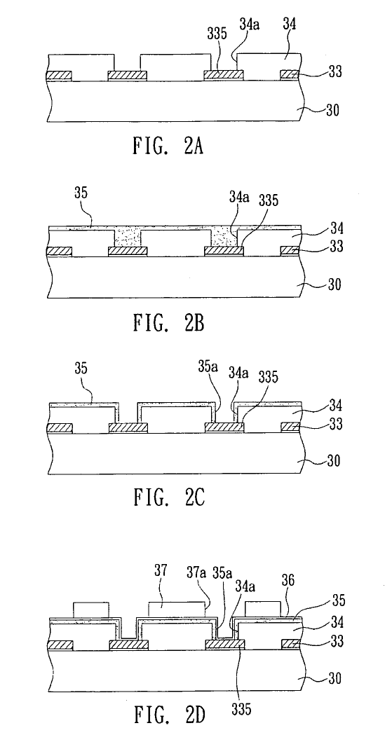

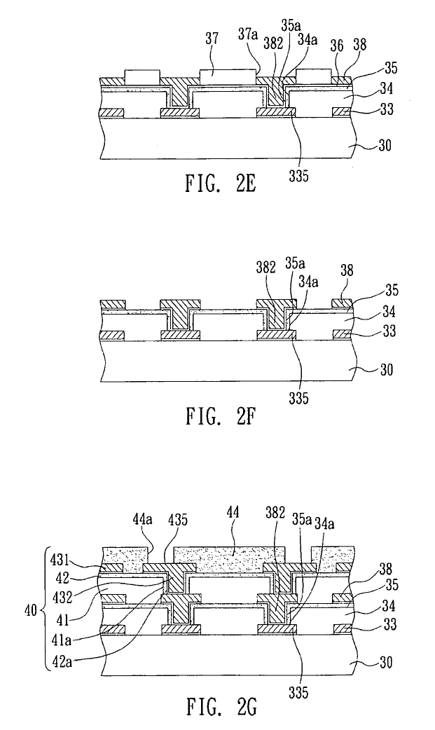

FIGS. 2A to 2G are diagrams showing a fabrication method of a circuit board according to the present invention.

As shown in FIG. 2A, a core board 30 such as a copper clad laminate (CCL) substrate or an insulative board is provided, wherein at least one surface thereof has has a core circuit layer 33. The core circuit layer 33 has a plurality of conductive lands 335. A first dielectric layer 34 is formed on the surface of the core board 30 and a plurality of openings 34a are formed in the first dielectric layer 34 by laser ablation or by exposure and development so as to expose the conductive lands 335.

As shown in FIG. 2B, a first coupling layer 35 is formed on the first dielectric layer 34 and on the conductive lands 335 in the openings 34a of the first dielectric layer 34.

As shown in FIG. 2C, parts of the first coupling layer 35 in the openings 34a of the first dielectric layer 34 is removed by laser ablation or by exposure and development so as to form a plurality of openings 35a for exposing parts of surfaces of the conductive lands 335.

As shown in FIG. 2D, a conductive seed layer 36 is formed on the first coupling layer 35 and in the openings 35a of the first coupling layer 35. Then, a resist layer 37 is formed on the conductive seed layer 36 and a plurality of openings 37a are formed in the resist layer 37 so as to expose parts of the conductive seed layer 36, wherein parts of the openings 37a correspond to the openings 35a of the first coupling layer 35.

As shown in FIG. 2E, a first circuit layer 38 is formed in the openings 37a of the resist layer 37 and a plurality of first conductive vias 382 are formed in the openings 35a of the first coupling layer 35 by electroplating through the conductive seed layer 36, wherein the first conductive vias 382 electrically connect to the conductive lands 335.

As shown in FIG. 2F, the resist layer 37 and the conductive seed layer 36 covered by the resist layer 37 are removed.

As shown in FIG. 2G, a circuit built-up structure 40 is further formed on the first circuit layer 38 and the first coupling layer 35, wherein the circuit built-up structure 40 comprises at least a second dielectric layer 41 with a plurality of openings 41a, a second coupling layer 42 formed on the second dielectric layer 41 and having a plurality of openings 42a corresponding to the openings 41a of the second dielectric layer 41, and a second circuit layer 431 formed on the second coupling layer 42 together with a plurality of second conductive vias 432 formed in the openings 42a of the second coupling layer 42, parts of the second conductive vias 432 electrically connecting to the first circuit layer 38, and the outermost second circuit layer 431 having a plurality of conductive pads 435. An insulative protection layer 44 such as a solder mask layer is further formed on the circuit built-up structure 40 and a plurality of openings 44a are formed in the insulative protection layer 44 so as to expose the conductive pads 435.

The present invention further provides a circuit board structure, as shown in FIG. 2G, which comprises: a core board 30, wherein at least one surface thereof has a core circuit layer 33, and the core circuit layer 33 has a plurality of conductive lands 335; a first dielectric layer 34 disposed on the core board 30 and having a plurality of openings 34a for exposing the conductive lands 335; a first coupling layer 35 disposed on the first dielectric layer 34 and having a plurality of openings 35a disposed corresponding to the openings 34a of the first dielectric layer 34; and a first circuit layer 38 disposed on the first coupling layer 35 and a plurality of first conductive vias 382 disposed in the openings 35a of the first coupling layer 35 for electrically connecting to the conductive lands 335.

The above structure further comprises a circuit built-up structure 40 disposed on the first circuit layer 38 and the first coupling layer 35, wherein the circuit built-up structure 40 comprises at least a second dielectric layer 41 with a plurality of openings 41a, a second coupling layer 42 disposed on the second dielectric layer 41 and having a plurality of openings 42a disposed corresponding to the openings 41a of the second dielectric layer 41, and a second circuit layer 431 disposed on the second coupling layer 42 together with a plurality of second conductive vias 432 disposed in the openings 42a of the second coupling layer 42, parts of the second conductive vias 432 electrically connecting to the first circuit layer 38, and the second circuit layer 431 having a plurality of conductive pads 435. An insulative protection layer 44 such as a solder mask layer is further disposed on the circuit built-up structure 40 and a plurality of openings 44a is disposed in the insulative protection layer 44 so as to expose the conductive pads 435.

As the first coupling layer 35 and the second coupling layer 42 have chemical bond characteristic through which the coupling layer of non-metal material can have a preferred bonding strength with the circuit layer of metal material, the first dielectric layer 34 and the second dielectric layer 41 are firmly connected to the core circuit layer 33, the first circuit layer 38 and the second circuit layer 431 through the first coupling layer 35 and the second coupling layer 42 respectively, thereby overcoming the conventional problems of micro cracks as well as peeling and delamination and meanwhile providing a strong bond strength for fine line circuits.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A circuit board, comprising:
a core board, wherein at least one surface thereof has a core circuit layer with a plurality of conductive lands;
a first dielectric layer disposed on the core board and having a plurality of openings for exposing the conductive lands;
a first coupling layer disposed on the first dielectric layer and having a plurality of openings disposed corresponding to the openings of the first dielectric layer; and
a first circuit layer disposed on the first coupling layer and a plurality of first conductive vias disposed in the openings of the first coupling layer for electrically connecting to the conductive lands.

2. The circuit board of claim 1 further comprising a circuit built-up structure disposed on the first circuit layer and the first coupling layer, wherein the circuit built-up structure comprises at least a second dielectric layer with a plurality of openings, a second coupling layer disposed on the second dielectric layer and having a plurality of openings disposed corresponding to the openings of the second dielectric layer; and a second circuit layer disposed on the second coupling layer together with a plurality of second conductive vias disposed in the openings of the second coupling layer, parts of the second conductive vias electrically connect to the first circuit layer, and the outermost second circuit layer has a plurality of conductive pads.

3. The circuit board of claim 2 further comprising an insulative protection layer disposed on the circuit built-up structure and having a plurality of openings for exposing the conductive pads.

4. A fabrication method of a circuit board, comprises:
providing a core board, wherein at least one surface thereof has a core circuit layer with a plurality of conductive lands, a first dielectric layer is formed on the core board, and a plurality of openings are formed in the first dielectric layer for exposing the conductive lands;
forming a first coupling layer on the first dielectric layer and on the exposed conductive lands in the openings of the first dielectric layer;
removing parts of the first coupling layer formed in the openings of the first dielectric layer so as to form a plurality of openings for exposing parts of surfaces of the conductive lands;
forming a conductive seed layer on the first coupling layer and in the openings of the first coupling layer;
forming a resist layer on the conductive seed layer and forming a plurality of openings in the resist layer for exposing parts of the conductive seed layer, wherein parts of the openings of the resist layer correspond to the openings of the first coupling layer;
forming a first circuit layer in the openings of the resist layer and forming first conductive vias in the openings of the first coupling layer by electroplating through the conductive seed layer, the conductive vias electrically connecting to the conductive lands; and
removing the resist layer and the conductive seed layer covered by the resist layer.

5. The fabrication method of claim 4, wherein the openings of the first dielectric layer are formed by laser ablation or by exposure and development.

6. The fabrication method of claim 4, wherein the openings of the first coupling layer are formed by laser ablation or by exposure and development.

7. The fabrication method of claim 4 further comprising forming a circuit built-up structure on the first circuit layer and the first coupling layer, wherein the circuit built-up structure comprises at least a second dielectric layer with a plurality of openings, a second coupling layer formed on the second dielectric layer and having a plurality of openings corresponding to the openings of the second dielectric layer; and a second circuit layer formed on the second coupling layer together with a plurality of second conductive vias formed in the openings of the second coupling layer, parts of the second conductive vias electrically connect to the first circuit layer, and the outermost second circuit layer has a plurality of conductive pads.

8. The fabrication method of claim 7 further comprising forming an insulative protection layer on the circuit built-up structure and forming a plurality of openings in the insulative protection layer for exposing the conductive pads.
